(19) United States
(12) Patent Application Publication
(10) Pub. No.: US 2026/0352236 A1
(43) Pub. Date: Nov. 5, 2026

(54) METHOD FOR ERROR CORRECTION AND DEVICE FOR ERROR PROCESSING

(71) Applicant: Infineon Technologies AG, Neubiberg (DE)

(72) Inventors: Thomas Kern, Aschheim (DE); Alexander Klockmann, Taufkirchen (DE); Michael Goessel, Mahlow (DE)

(21) Appl. No.: 19/658,982

(22) Filed: Apr. 27, 2026

(30) Foreign Application Priority Data
Apr. 30, 2025 (DE) 10 2025 116 613.7

(51) Int. Cl. H03M 13/15; H03M 13/09

(52) U.S. Cl. CPC H03M 13/152; H03M 13/098; H03M 13/1575

(57) ABSTRACT

The approaches proposed here relate to the correction of a 1-bit error by means of a BCH code which can correct at least two bit errors, wherein an i-th bit is corrected if the following condition is satisfied: a first syndrome component of an error syndrome in combination with a first element of a Galois field satisfies a first predetermined condition and a second component of the error syndrome in combination with a second element of the Galois field satisfies a second predetermined condition, wherein the second element of the Galois field is determined by the first element of the Galois field.

### REFERENCE TO RELATED APPLICATION

This application claims priority to German Application number 10 2025 116 613.7, filed on Apr. 30, 2025, the contents of which are hereby incorporated by reference in their entirety.

### FIELD

The present approaches relate to error processing and/or error correction.

### SUMMARY

The problem addressed is to improve existing approaches and, in particular, to create a means for high-performance correction of 1-bit errors.

This problem is solved in accordance with the features of the independent claims. Preferred embodiments can be gathered from the dependent claims, in particular.

These examples proposed herein may be based on at least one of the following solutions. In particular, combinations of the following features can be used to achieve a desired result. The features of the device may be combined with features of the method or vice versa.

For the solution, a method is proposed for correcting a 1-bit error by means of a Bose-Chaudhuri-Hocquenghem (BCH) code which can correct at least two bit errors, wherein an i-th bit is corrected if the following condition is satisfied: a first syndrome component of an error syndrome in combination with a first element of a Galois field satisfies a first predetermined condition and a second component of the error syndrome in combination with a second element of the Galois field satisfies a second predetermined condition, wherein the second element of the Galois field is determined by the first element of the Galois field.

In a development of the invention, the i-th bit is corrected if the first element of the Galois field is equal to the element of the Galois field associated with the i-th bit position.

In one development,
the error syndrome has a first syndrome component s₁ and a second syndrome component s₃,
the first predefined condition is that the first syndrome component s₁ added to the first element of the Galois field equals 0,
the second predefined condition is that the second syndrome component s₃ added to the second element of the Galois field equals 0,
the second element of the Galois field is determined as the third power of the first element of the Galois field,
wherein the Galois field is determined to GF(2^{m}).

In one development,
the element assigned to the i-th bit position is equal to αⁱ,
the first predefined condition is determined by

s₁+αⁱ=0,
the second predefined condition is determined by

s₃+α³ⁱ=0,
where “+” corresponds to the addition in the Galois field.

In one development, the elements of the Galois field in their vector representation are m-component vectors and

(s₁+αⁱ,s₃+α³ⁱ)

is a 2m-component binary vector.

In one development, the i-th bit is not corrected if the condition is not satisfied.

In one development, the BCH code is a shortened BCH code.

In one development, the BCH code is a BCH code with parity.

In one development, a correction signal for a bit is determined if the first syndrome component or the second syndrome component is/are unequal to 0 and the parity assumes a value that does not correspond to a 1-bit error.

In one development, a correction signal for one bit of a multi-bit error is determined if an error has occurred that is not a 1-bit error.

In one development, the correction is made using a modified locator polynomial and in order to form a coefficient of the modified locator polynomial a constant is added to a coefficient of the locator polynomial when no error or a 1-bit error is determined.

In one development, a correction signal for a bit position is determined by a logical OR combination of a correction signal determined for the bit position for correcting the 1-bit error and a correction signal determined for the bit position for correcting a multi-bit error.

Furthermore, a device for error processing is proposed,
comprising a first partial circuit for determining a first correction signal, if no error is determined or a 1-bit error is determined,
comprising a second partial circuit for determining a second correction signal, if at least one multi-bit error is determined,
wherein the first partial circuit and the second partial circuit are configured in such a way that either the first correction signal or the second correction signal is active.

In one development, the first correction signal and the second correction signal are combined by means of a gate, in particular an OR gate.

In one development, the first correction signal occurs faster than the second correction signal and the first correction signal is structured in such a way that it can be used if no correction is carried out.

In one development, in the event of an error, the at least one multi-bit error is corrected using the second error correction signal if the first correction signal does not lead to an error correction.

In one development, the first partial circuit for determining the first correction signal comprises a gate logic, on the basis of which it can be tested whether the following condition for correcting an i-th bit is satisfied: a first syndrome component of an error syndrome in combination with a first element of a Galois field satisfies a first predefined condition and a second component of the error syndrome in combination with a second element of the Galois field satisfies a second predefined condition, wherein the second element of the Galois field is determined by the first element of the Galois field.

In one development,
the error syndrome has a first syndrome component s₁ and a second syndrome component s₃,
the first predefined condition is that the first syndrome component s₁ added to the first element of the Galois field equals 0,
the second predefined condition is that the second syndrome component s₃ added to the second element of the Galois field equals 0,
the second element of the Galois field is determined as the third power of the first element of the Galois field,
the Galois field is determined to GF(2^{m}).

In one development,
the element assigned to the i-th bit position is equal to αⁱ,
the first predefined condition is determined by

s₁+αⁱ=0,
the second predefined condition is determined by

s₃+α³ⁱ=0,
where “+” corresponds to the addition in the Galois field.

In one development, the first predefined condition and the second predefined condition are implemented by means of a NOR logic.

In one development, the second partial circuit for determining the correction signal is configured to generate a control signal based on the first syndrome component s₁, so that, depending on this control signal, a single bit can be changed so that in the event that the first partial circuit indicates that there is no error or a 1-bit error is present, the second partial circuit always indicates that no multi-bit error is present.

In one development, the second partial circuit for determining the correction signal comprises logical combinations of multiple syndrome components of an error signal with multiple elements of the Galois field, so that it can be tested whether the at least one multi-bit error is present.

A device for error processing is also proposed, comprising circuit elements and/or at least one processing unit which is/are configured to carry out the steps of the method described herein.

### BRIEF DESCRIPTION OF THE DRAWINGS

The above-described properties, features and advantages of this invention and the way in which they are achieved will be explained further in association with a schematic description of exemplary embodiments which are explained in greater detail in association with the drawings. For the sake of clarity, identical or identically acting elements may be provided with identical reference signs.

FIG. 1 shows an example circuit arrangement for correcting a 1-bit error.

FIG. 2 shows an example circuitry or circuit arrangement for the fast correction of a 1-bit error.

FIG. 3 shows an example circuitry or circuit arrangement for the fast correction of a 1-bit error combined with a correction of a 2-bit error.

FIG. 4 shows an alternative embodiment of a combination of the fast correction of a 1-bit error with a correction of a 2-bit error.

FIG. 5 shows an exemplary embodiment of a combination of the fast correction of a 1-bit error with a correction of a 2-bit error and a correction of a 3-bit error.

FIG. 6 shows an example implementation of the formation of the value K₀+eα⁰ of the modified locator polynomial L₃(x)^{mod}.

### DETAILED DESCRIPTION

2-bit error correcting BCH codes or 2-bit error correcting and 3-bit error detecting BCH codes can be used to correct 1-bit errors and 2-bit errors, and 3-bit error correcting BCH codes or 3-bit error correcting and 4-bit error detecting BCH codes can be used to correct 1-bit errors, 2-bit errors and 3-bit errors. The correction of errors by BCH codes is described, for example, in
Wicker S., Error Control Systems for Digital Communication and Storage, Prentice Hall, 1995, Seiten 203-214,
Lin S., Costello D., Error Control Coding, Prentice Hall, 1983, pages 141-160,
Okano H., Imai H., A Construction Method of High-Speed Decodes Using ROM's For Bose-Chauddhuri-Hocquenghem and Reed-Solomon Codes, IEEE Trans Computers, C-36, No 10, pages 1165-1171.

A method for 3-bit correction and operations in a Galois field are described in DE 10 2014 215 252, for example.

An exemplary goal of the solutions described here is to improve the 1-bit correction for a t-bit error correcting or for a t-bit error correcting and (t+1)-bit error detecting BCH code over a Galois field GF(2^{m}). In particular, t≥2 and m≥4.

Here, the correction of a 1-bit error or a 2-bit error is performed using an example of a 2-bit error correcting BCH code, the code distance of which is 5. If an overall parity is included, the code distance evaluates to 6.

Here, the correction of a 1-bit error, a 2-bit error or a 3-bit error is performed using an example of a 3-bit error correcting BCH code, the code distance of which is 7. If the overall parity is included, the code distance evaluates to 8.

A t-bit error correcting BCH code can be described, for example, by an H matrix

$$H = ( {h}_{0} , {h}_{1} , … , {h}_{n - 1} ) = ( \begin{matrix}{H}_{1} \\ {H}_{3} \\ ⋮ \\ {H}_{2 t - 1}\end{matrix} )$$

with the columns h₀, h₁, . . . , hₙ₋₁, where

hᵢ=[αⁱ,α^{3·i},α^{5·i}, . . . ,α^{2(t-1)·i}]^{T}
for i=0, . . . , n−1.
For t=2, the H matrix evaluates to

$$H = ( {h}_{0} , {h}_{1} , … , {h}_{n - 1} ) = ( \begin{matrix}{H}_{1} \\ {H}_{3}\end{matrix} )$$

where

H₁=(α⁰,α¹,α², . . . ,αⁿ⁻¹),

H₃=(α⁰,α³,α⁶, . . . ,α³⁽ⁿ⁻¹⁾).
If parity is included, then

$$H = ( {h}_{0} , {h}_{1} , … , {h}_{n - 1} ) = ( \begin{matrix}{H}_{1} \\ {H}_{3} \\ {H}_{P}\end{matrix} )$$

$$with {H}_{P} = {\underbrace{( 1 , … , 1 ]}}_{n} .$$

For t=3, the H matrix evaluates to

$$H = ( {h}_{0} , {h}_{1} , … , {h}_{n - 1} ) = ( \begin{matrix}{H}_{1} \\ {H}_{3} \\ {H}_{5}\end{matrix} )$$

where

H₁=(α⁰,α¹,α², . . . ,αⁿ⁻¹),

H₃=(α⁰,α³,α⁶, . . . ,α³⁽ⁿ⁻¹⁾),

H₅=(α⁰,α⁵,α¹⁰, . . . ,α⁵⁽ⁿ⁻¹⁾).
If parity is included, then

$$H = ( {h}_{0} , {h}_{1} , … , {h}_{n - 1} ) = ( \begin{matrix}{H}_{1} \\ {H}_{3} \\ {H}_{5} \\ {H}_{P}\end{matrix} )$$

$$with {H}_{P} = {\underbrace{( 1 , … , 1 ]}}_{n} .$$

The exponents of a are to be interpreted modulo (2^{m}−1). Here αⁱ, α^{3·i} α^{5·i}, . . . are elements of the Galois field GF(2^{m}) with m≥4 and n≤2^{m}−1.
The term

[αⁱ,α^{3·i},α^{5·i}, . . . ,α^{2(t-1)·i}]^{T}
designates a column vector. In this case

αⁱ,α^{3·i},α^{5·i}, . . . ,α^{2(t-1)·i}
can also be referred to as components of the column vector. A component of the column vector is thus an element of the Galois field GF(2^{m}).

In the following, by way of example α=α¹ is selected as a generating element of the Galois field, so that αⁱ for i=0, . . . , 2^{m}−1 assumes all elements unequal to 0 of the Galois field GF(2^{m}).

The code distance is 2t+1, and the addition of 2·t arbitrary columns of the H matrix is not equal to 0. If the components of the H-matrix are used as m-digit binary vectors or as binary m-tuples in their vector representation, then the addition of the columns can be realized as an exclusive OR logical combination (also referred to as XOR logical combination) of the corresponding bits of the columns.

For t=2 the code distance is equal to 5 and 2-bit errors can be corrected. For t=3 the code distance is 7 and 3-bit errors can be corrected.

For an n-component binary vector

$${v}^{′} = {v}_{0}^{′} , {v}_{1}^{′} , … , {v}_{n - 1}^{′}$$

is an error syndrome s with syndrome components s₁ and s₃ for a 2-bit error correcting BCH code is determined as

s₁=H₁·[v′]^{T} and s₃=H₃·[v′]^{T}.

For a 3-bit error correcting BCH code, the error syndrome s with the syndrome components s₁, s₃ and s₅ is determined as

s₁=H₁·[v′]^{T},s₃=H₃·[v′]^{T} and s₅=H₅·[v′]^{T}.
If parity is also taken into account, the parity P of the vector v′ is determined according to

$$P = {H}_{P} \cdot {[ {v}^{′} ]}^{T} = {v}_{0}^{′} + {v}_{1}^{′} + ⋯ {v}_{n - 1}^{′} .$$

The syndrome components s₁, s₃ and s₅ are elements of the Galois field GF(2^{m}) and the parity P is equal to either 0 or 1. In their vector representation, the syndrome components are m-digit binary vectors or binary m-tuples.

The first component in the i-th column of hᵢ of an H-matrix according to one of the equations ([HMatrix1]), ([HMatrix11]), ([HMatrix14]), ([HMatrix12]), ([HMatrix15]) will be referred to as the element assigned to the i-th column or the i-th bit position.

If the column hᵢ is determined according to the equation above, then αⁱ is the element of the Galois field assigned to the i-th bit position.

It is an option to arrange the columns according to equation above of the H-matrix according to equation ([HMatrix1]) in a different order and, for example, to swap the i-th column with the j-th column.

If not all possible n=2^{m}−1 columns of the H-matrix are used, this can be referred to as a shortened code. In general, a code can be shortened by deleting columns in the H-matrix. The BCH codes mentioned herein may be shortened or unshortened codes.

The exponents of the elements are to be interpreted modulo 2^{m}−1.

For a better overview, in the following the element ai is assigned to the i-th bit position and the column hᵢ of the H-matrix according to equation above is used.

The elements or components αⁱ, α^{3·i} and α^{5·i} of the Galois field GF(2^{m}) can be specified in their vector representation as m-digit binary vectors or as binary m-tuples.

In the H-matrix according to equation ([HMatrix1]), a column hᵢ may have binary components in its vector representation t·m.

For example, for t=2, m=5 and n=31 the H matrix can be specified in the form

$$H = ( \begin{matrix}{α}^{0} & {α}^{1} & {α}^{2} & … & {α}^{30} \\ {α}^{0} & {α}^{3} & {α}^{6} & … & {α}^{28}\end{matrix} )$$

The component α²⁸ in the second row and the last (i.e. the 31st) column is obtained from α^{3·30}=α⁹⁰=α²⁸, since the exponents of a are to be taken as modulo 31, and 90 modulo 31=28.

In this example, the element α⁰ is assigned to the 0-th bit position, the element α¹ to the 1st bit position, the element α² to the 2nd bit position, and in general the element αⁱ is assigned to the i-th bit position.

Instead of the H-matrix according to equation ([Hmatrix41]), an H-matrix H* with

$${H}^{*} = ( \begin{matrix}{α}^{2} & {α}^{1} & {α}^{0} & … & {α}^{30} \\ {α}^{6} & {α}^{3} & {α}^{0} & … & {α}^{28}\end{matrix} )$$

can also be used, in which the 0-th column has been swapped with the 2nd column, for example. In this case, the element α² is assigned to the 0-th bit position and the element α⁰ to the second bit position.

### Correction of 1-Bit Errors or 2-Bit Errors

For example, an error correction of 1-bit errors and 2-bit errors can be implemented as follows:

For each bit position i to be corrected, locator polynomials L₁(x) and L₂(x) can have a value of 0 or a value unequal to 0, depending on the element assigned to the respective bit position.

The locator polynomials L₁(x) and L₂(x) are determined as follows:

$${L}_{1} ( x ) = {s}_{1} + x$$

$${L}_{2} ( x ) = {s}_{1}^{3} + {s}_{3} + {s}_{1} {x}^{2} + {s}_{1}^{2} x$$

These are first and second degree locator polynomials of a 2-bit error correcting BCH code.

The locator polynomial L₁(x) is a linear function in x. By replacing the variable x by an element αⁱ of the Galois field, the value L₁(αⁱ) follows from L₁(x) or the value L₂(αⁱ) from L₂(x).

For an i-th bit position, it is checked whether

L₁(αⁱ)=s₁+αⁱ=0
is true and whether

$${L}_{2} ( {α}^{i} ) = {s}_{1}^{3} + {s}_{3} + {s}_{1}^{2} {α}^{i} + {s}_{1} {α}^{2 i} = 0$$

is true.

In the case of a 1-bit error in the i-th bit position, the error syndrome is equal to the i-th column of the H-matrix, it is s₁=αⁱ and the following applies:

L₁(αⁱ)=s₁+αⁱ=αⁱ+αⁱ=0.
For j≠i on the other hand, the following applies:

L₁(α^{j})=s₁+α^{j}=αⁱ+α^{j}≠0.

In the case that no bit error is detected, the following applies

s₁=0,

s₃=0.
This means that:

L₁(αⁱ)=αⁱ≠0,

L₂(αⁱ)=0
for each αⁱ.

Thus, if it is determined that a 1-bit error has occurred, the bit position i of the 1″ bit error can be determined by the locator polynomial L₁(x)
for x=αⁱ assuming the value L₁(αⁱ)=0 and
for all other bit positions j with j≠i the following applies: L₁(α^{j})=αⁱ+α^{j}≠0.
In the case of a 2-bit error in the bit positions i and j,

s₁=αⁱ+α^{j}.
If α^{k} is defined according to

α^{k}=αⁱ+α^{j},
in the case of this 2-bit error:

L₁(α^{k})=s₁+α^{k}=αⁱ+α^{j}+α^{k}=0.

The value L₁(α^{k})=0 then incorrectly indicates that there is a 1-bit error in the k-th bit position, although there is actually a 2-bit error in the bit positions i and j. This could lead to a false correction.

If there is no bit error, then s₁=0 applies and hence L₁(αⁱ)≠0 for i=0, . . . , n−1. Thus, the first degree locator polynomial L₁(αⁱ) for any bit position i does not indicate an incorrect bit position.

In order to avoid a false correction in the case of the 2-bit error using the locator polynomial L₁, it can also be determined whether a 1-bit error or a 2-bit error is present. For this purpose, for example, a supplementary check is carried out to determine whether the condition

$${s}_{1}^{3} + {s}_{3} = 0$$

is satisfied or not.

In the case of the 1-bit error in any bit position k, with s₁=α^{k} and s₃=α^{3k}:

$${s}_{1}^{3} + {s}_{3} = {α}^{3 k} + {α}^{3 k} = 0$$

The following applies to the 2-bit error:

$${s}_{1}^{3} + {s}_{3} \neq 0 .$$

This can be explained as follows: If the 2-bit error occurs in any two bit positions j and k, then with

s₁=α^{j}+α^{k} and s₃=α^{3j}+α^{3k}

the following relationship applies:

$$\begin{matrix}{s}_{1}^{3} + {s}_{3} = {( {α}^{j} + {α}^{k} )}^{3} + {α}^{3 j} + {α}^{3 k} = \\ = ( {α}^{3 j} + {α}^{3 k} + {α}^{2 j} {α}^{k} + {α}^{2 k} {α}^{j} ) + {α}^{3 j} + {α}^{3 k} = \\ = {α}^{2 j} {α}^{k} + {α}^{2 k} {α}^{j} = \\ = {α}^{j} {α}^{k} ( {α}^{j} + {α}^{k} ) \neq 0\end{matrix}$$

$$for {α}^{j} \neq {α}^{k} .$$

The first degree locator polynomial according to equation above can therefore only be used to determine the bit position of a 1-bit error if due to the validity of

$${s}_{1}^{3} + {s}_{3} = 0$$

it is determined that there is a 1-bit error and not a 2-bit error.

If, on the other hand,

$${s}_{1}^{3} + {s}_{3} \neq 0 ,$$

there is no 1-bit error present. In this case, the second degree locator polynomial L₂ according to equation above is used to indicate a 2-bit error in the bit positions i and j by L₂(αⁱ)=0 and L₂(α^{j})=0. The bit positions i and j are incorrect and should be corrected. For all other bit positions L₂, the locator polynomial is not equal to 0.

This relationship can be illustrated as follows: For a 2-bit error in the bit positions i and j with

s₁=(αⁱ+α^{j})

s₃=(α³ⁱ+α^{3j})

with equation above the following applies:

$$\begin{matrix}{L}_{2} ( {α}^{i} ) = {s}_{1}^{3} + {s}_{3} + {s}_{1}^{2} {α}^{i} + {s}_{1} {α}^{2 i} = \\ = {α}^{i} {α}^{j} ( {α}^{i} + {α}^{j} ) + ( {α}^{i} + {α}^{j} ) {α}^{2 i} + {( {α}^{i} + {α}^{j} )}^{2} {α}^{i} = \\ = {α}^{2 i} {α}^{j} + {α}^{2 j} {α}^{i} + {α}^{3 i} + {α}^{2 i} {α}^{j} + {α}^{3 i} + {α}^{2 j} {α}^{i} = 0\end{matrix} .$$

This takes into account the fact that two equal values in the Galois field GF(2^{m}) add up to 0.
L₂(α^{j})=0 and L₂(α^{k})≠0 follow accordingly for k≠i,j.
   Correction of 1-Bit Errors with Delay

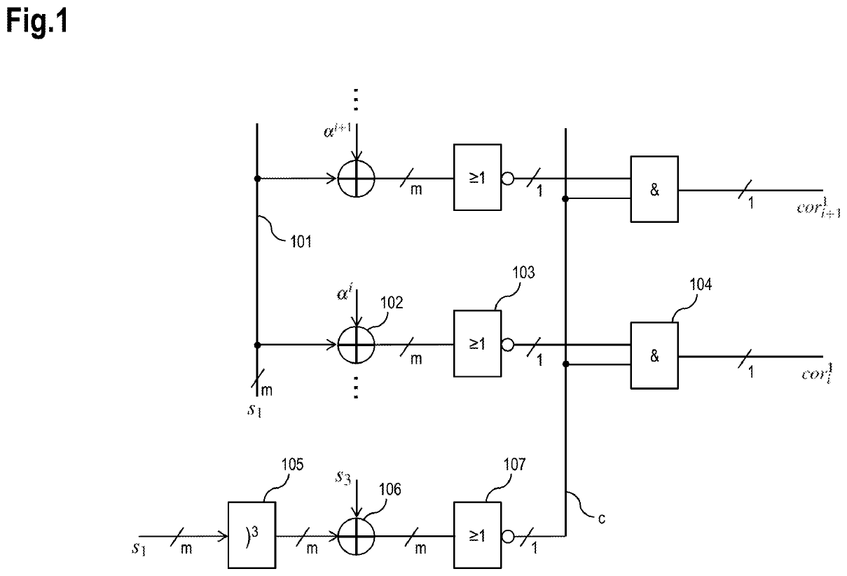

FIG. 1 shows an example circuit arrangement for correcting a 1-bit error. For this purpose, a correction signal

$$c o {r}_{i}^{1}$$

is determined for an i-th bit

$${v}_{i}^{′}$$

to be corrected of a possibly incorrect bit vector v′.

On an m-bit wide line 101, the syndrome component s₁ of the error syndrome is provided in its vector representation as an m-component binary vector.

The syndrome component s₁ is XOR-combined component-by-component with the value αⁱ assigned to the bit position i by means of an XOR gate 102. The m outputs of the XOR gate 102 are connected to m inputs of a NOT-OR gate 103 (also referred to as a NOR gate). The NOR gate 103 has an output that only returns the value 1 if the value 0 is present at all m inputs. The output of the NOR gate 103 is connected to the first input of an AND gate 104, and the correction signal

$$c o {r}_{i}^{1}$$

is provided at the output of the AND gate 104. A control value c is present at the second input of the AND gate 104. If the control value c is equal to 1, the correction signal

$$c o {r}_{i}^{1}$$

is equal to the value of the output of the NOR gate 103, otherwise the correction signal

$$c o {r}_{i}^{1}$$

Is equal to 0.

The correction signal

$$c o {r}_{i}^{1}$$

Is used for the i-th component

$${v}_{i}^{′}$$

of the bit vector v′ to be corrected, which is XOR-combined with the component

$${v}_{i}^{′}$$

to form a corrected value

$${v}_{i}^{c o r} = {v}_{i}^{′} + c o {r}_{i}^{1}$$

The component-wise logical combination of the syndrome component s₁ with the value αⁱ in the XOR gate 102 can be carried out, for example, in such a way that the binary components of the syndrome component s₁ are inverted in the positions where the corresponding components of αⁱ are equal to 1 and remain unchanged in the positions where αⁱ is equal to 0.

The control signal c is

$$equal to 1 if {s}_{1}^{3} + {s}_{3} = 0 or$$

$$equal to 0 if {s}_{1}^{3} + {s}_{3} \neq 0 applies .$$

The control signal c is determined based on the syndrome components s₁ and s₃ by means of a third power generator 105 (with m inputs and m outputs), an adder 106 (with m inputs and m outputs) and a NOR gate 107 (with m inputs and one output).

The value of the syndrome component s₁ is present at the input of the third power generator 105, the output of the third power generator 105 is connected to the first input of the adder 106. The value of the syndrome component s₃ is present at the second input of the adder 106. The output of the adder 106 is connected to the input of the NOR gate 107, the output of the NOR gate returns the control signal c and is connected to the second input of the AND gate 104.

It is a disadvantage here that the control signal c and hence also the correction signal

$$c o {r}_{i}^{1}$$

can only be delivered with a considerable delay due to the gate propagation times.

FIG. 1 also shows a corresponding addition to the circuit for a bit position (i+1), which also delivers a correction signal

$${cor}_{i + 1}^{1}$$

based on the control signal c. This illustrates which part of the circuit should be provided for each bit position.

### Quick Correction of a 1-Bit Error

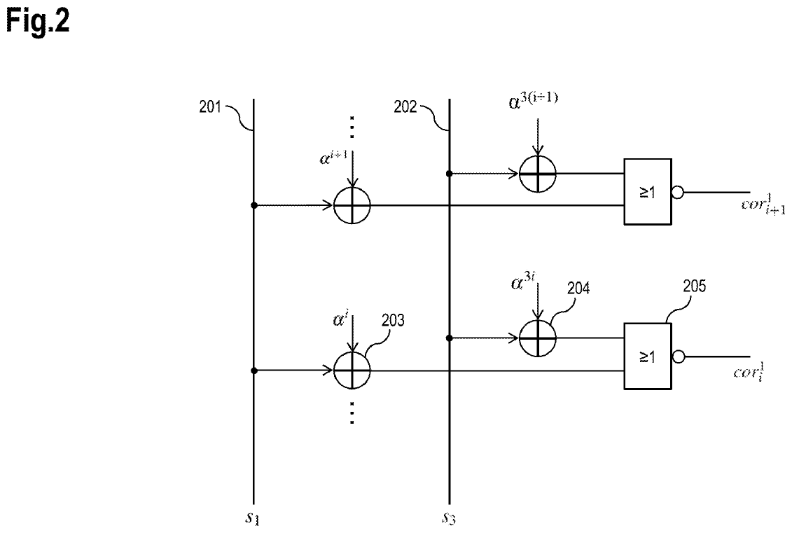

FIG. 2 shows an example circuit arrangement for the quick correction of a 1-bit error.

On an m-bit-wide line 201, the syndrome component s₁ is provided as a binary vector with m components, and on an m-bit-wide line 202, the syndrome component s₃ is provided as a binary vector with m components.

A correction signal

$${cor}_{i}^{1}$$

for the i-th component

$${v}_{i}^{′}$$

of the binary vector v′ to be corrected is determined as follows:

The syndrome component s₁ is XOR-combined component-by-component with the value αⁱ assigned to the bit position i by means of an XOR gate 203. The syndrome component s₃ is XOR-combined component-by-component with the third power α³ⁱ of the value assigned to the bit position i by means of an XOR gate 204. The output of the XOR gate 203 and the output of XOR gate 204 are connected to two different inputs of a NOR gate 205. The correction signal

$${cor}_{i}^{1}$$

is provided at the output of the NOR gate 205.

The NOR gate 205 is used to check whether the conditions

s₁+αⁱ=0 and

s₃+α³ⁱ=0

are satisfied. Only then, i.e. if both conditions are satisfied, should the i-th bit position be corrected and only then does the correction signal

$${cor}_{i}^{1}$$

receive the value 1.

This avoids a false correction in cases where there is no bit error, or a 1-bit error, a 2-bit error or a 3-bit error is present. Advantageously it is not necessary to additionally determine the number of errors that have occurred. This means that the correction signal

$${cor}_{i}^{1}$$

for an incorrect single bit is available quickly. It is not necessary to form a control value.

The values αⁱ and α³ⁱ for the respective i-th bit position are known and the logical XOR combinations of the syndrome component s₁ with the value αⁱ and the syndrome component s₃ with the value α³ⁱ can be implemented by inverters for the individual components (i.e. bits) of the syndrome components s₁ and s₃ if the values αⁱ and α³ⁱ are equal to or 1.

If no bit error is determined, the syndrome components s₁ and s₃ are equal to 0 and the following applies for each bit position k:

s₁+α^{k}≠0

s₃+α^{3k}≠0

This, the correction signal

$${cor}_{k}^{1}$$

is equal to 0.

In the case of a 1-bit error in bit position i, s₁=αⁱ and s₃=α³ⁱ applies. Because of

$${s}_{1} + {α}^{k} = {α}^{i} + {α}^{k} = \{ \begin{matrix}0 & for k = i \\ \neq 0 & for k \neq i\end{matrix}$$

$${s}_{3} + {α}^{3 k} = {α}^{3 i} + {α}^{3 k} = \{ \begin{matrix}0 & for k = i \\ \neq 0 & for k \neq i\end{matrix}$$

the correction signal is

$${cor}_{i}^{1} = 1$$

for k=i. For k≠i the correction signal is

$${cor}_{i}^{1} = 0$$

and the 1-bit error is corrected.

For a 2-bit error in the bit positions i and j the following applies:

s₁=αⁱ+α^{j},

s₃=α³ⁱ+α^{3j}.

For the 2-bit error, it is not possible for the following conditions to apply at the same time

s₁+α^{k}=0,

s₃+α^{3k}=0

for an arbitrary value α^{k}≠0, because

s₁+α^{k}=αⁱ+α^{j}+α^{k}=0

and

s₃+α^{3k}=α³ⁱ+α^{3j}+α^{3k}=0

leads to a contradiction.

Thus, for i=k:

s₁+αⁱ=αⁱ+α^{j}+αⁱ=α^{j}≠0,

s₃+α³ⁱ=α³ⁱ+α^{3j}+α³ⁱ=α^{3j}≠0,

and correspondingly for j=k:

s₁+α^{j}=αⁱ≠0,

s₃+α^{3j}=α³ⁱ≠0,

so that in the following, it can be assumed that i, j and k are pairwise different.

From equation above it follows that

αⁱ=α^{j}+α^{k}
and

$$\begin{matrix}{α}^{3 i} = {α}^{2 i} \cdot {α}^{i} = \\ = {( {α}^{j} + {α}^{k} )}^{2} ( {α}^{j} + {α}^{k} ) = \\ = ( {α}^{2 j} + {α}^{2 k} ) ( {α}^{j} + {α}^{k} ) = \\ = {α}^{3 j} + {α}^{3 k} + {α}^{2 j} {α}^{k} + {α}^{2 k} {α}^{j} = \\ = {α}^{3 j} + {α}^{3 k} + {α}^{j} {α}^{k} ( {α}^{j} + {α}^{k} )\end{matrix}$$

With the equation above it follows that

α³ⁱ=α^{3j}+α^{3k}

and hence

α^{j}α^{k}(α^{j}+α^{k})=0.

This is a contradiction, since

α^{k}≠α^{j}≠0
is true.

For all bit positions to be corrected k, the correction signal is

$${cor}_{k}^{1} = 0$$

and no false corrections occur.

Even for a 3-bit error, a false correction is impossible, since the conditions s₁+α^{k}=0 and s₃+α^{3k}=0 are not simultaneously satisfied for the 3″ bit error.

For the 3-bit error in bit positions i, j, m the following apply

s₁=αⁱ+α^{j}+α^{m}

s₃=α³ⁱ+α^{3j}+α^{3m}

and the conditions

s₁+α^{k}=αⁱ+α^{j}+α^{m}+α^{k}=0

s₃+α^{3k}=α³ⁱ+α^{3j}+α^{3k}+α^{3m}=0

lead, as above in the case of the 2-bit error, to a contradiction.

Thus, for i=k:

s₁+α^{k}=α^{j}+α^{m}≠0.

Accordingly, the following applies for j=k:

s₁+α^{k}=αⁱ+α^{m}≠0.

It is also true for k=m:

s₁+α^{k}=αⁱ+α^{j}≠0.

Thus, it can be assumed in the following that i, j, m and k are pairwise different.

From the equation above it follows that

αⁱ=α^{j}+α^{k}+α^{m}

and

$$\begin{matrix}{α}^{3 i} = {α}^{2 i} \cdot {α}^{i} = \\ = {( {α}^{j} + {α}^{k} + {α}^{m} )}^{2} ( {α}^{j} + {α}^{k} + {α}^{m} ) = \\ = ( {α}^{2 j} + {α}^{2 k} + {α}^{2 m} ) ( {α}^{j} + {α}^{k} + {α}^{m} ) = \\ = {α}^{3 j} + {α}^{3 k} + {α}^{3 m} + {α}^{2 j} {α}^{k} + {α}^{2 j {α}^{k}} + \\ {α}^{2 k} {α}^{j} + {α}^{2 k} {α}^{m} + {α}^{2 m} {α}^{j} + {α}^{2 m} {α}^{k} = \\ = {α}^{3 j} + {α}^{3 k} + {α}^{3 m} + ( {α}^{j} + {α}^{k} ) ( {α}^{j} + {α}^{m} ) ( {α}^{k} + {α}^{m} )\end{matrix}$$

From the equation above it follows that:

α³ⁱ=α^{3j}+α^{3k}+α^{3m}.

and hence

(α^{j}+α^{k})(α^{j}+α^{m})(α^{k}+α^{m})=0,

which is a contradiction, because α^{j}, α^{k} and α^{m} are pairwise different.

In other words: If a 1-bit error has occurred, an error correction is made exactly in the bit position containing the error.

If there is no error present in any bit position, or if there are errors in two bit positions, or if there are errors in three bit positions, then the solution for 1-bit correction presented here does not perform a correction in any bit position.

It is not necessary to additionally check whether a 1-bit error was also actually present. No false correction is made in a bit position that is not incorrect.

It is an option to use a 1-bit correction circuit as a partial circuit of an error correction circuit, which corrects, for example, 1-bit errors and 2-bit errors or corrects 1-bit errors, 2-bit errors and 3-bit errors.

A 2-bit error-correcting and 3-bit error-detecting BCH code can be described by an H-matrix according to equation ([HMatrix14]), which contains a row of ones and for which the syndrome components s₁, s₃ and parity P are determined.

If 1-bit errors and 2-bit errors are to be corrected, the 1-bit error correction proposed here can be used if either no error occurred or a 1-bit error occurred. The examples given here provide a fast correction of the 1-bit error, which is advantageous because 1-bit errors occur more frequently than 2-bit errors or 3-bit errors. If a multi-bit error does occur, the more time-consuming correction can be performed in a targeted manner. Since in many applications most data words are error-free and do not need to be corrected, few data words have a 1-bit error and much fewer data words have a multi-bit error, the approach proposed here allows a significant increase in performance.

The m-bit wide syndrome component s₁ and the parity P are sufficient to distinguish whether there is no bit error, a 1-bit error, or a 2-bit error.

For the error-free case, the following applies: s₁=0 and P=0.

For a 1-bit error, the following applies: s₁≠0 and P=1.

For a 2-bit error, the following applies: s₁≠0 and P=0.

Fast Correction of the 1-Bit Error Combined with Correction of the 2-Bit Error

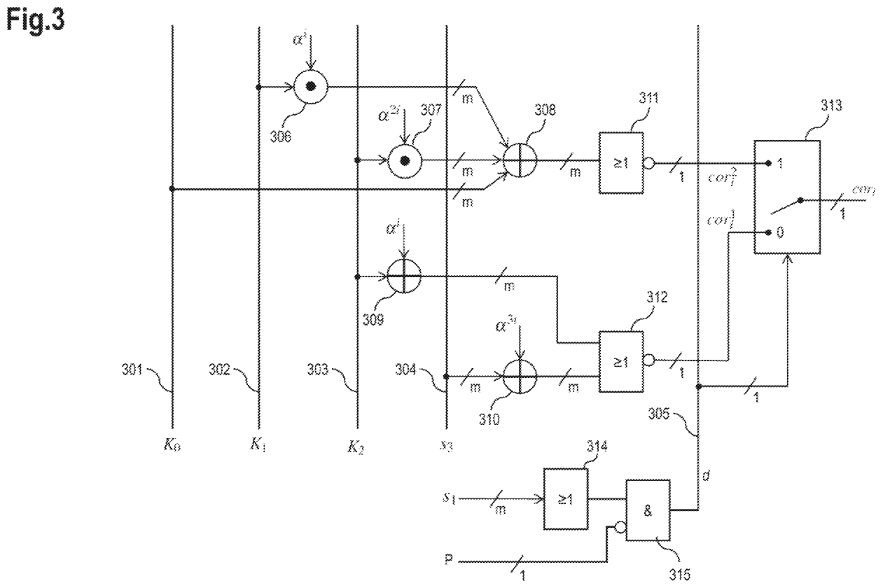

FIG. 3 shows an example circuit arrangement for the fast correction of a 1-bit error combined with a correction of a 2-bit error. For example, a 2-bit error correcting BCH code with parity can be used.

The correction of a 2-bit error is carried out using the second degree locator polynomial

$${L}_{2} ( x ) = {K}_{0} + {K}_{1} x + {K}_{2} {x}^{2} = {s}_{1}^{3} + {s}_{3} + {s}_{1}^{2} x + {s}_{1} {x}^{2}$$

with the coefficients

$${K}_{0} = {s}_{1}^{3} + {s}_{3} ,$$

$${K}_{1} = {s}_{1}^{2} ,$$

$${K}_{2} = {s}_{1} .$$

On an m-bit wide line 301 the coefficient K₀ is provided, on an m-bit wide line 302 the coefficient K₁, on an m-bit wide line 303 the coefficient K₂, on an m-bit wide line 304 the syndrome component s₃ is provided and on a 1-bit wide line 305, a value d of a control signal is provided for all bit positions to be corrected.

In the example shown in FIG. 3, the bit position i is to be corrected. To do this, a correction signal

$${cor}_{i}^{2}$$

is determined to correct any 2-bit error that has occurred in the bit position i.

Also provided in FIG. 3 are multipliers 306, 307 with m inputs and m outputs each, an adder 308 with three m inputs, adders 309, 310 with two m inputs and m outputs each, a NOR gate 311 with m inputs and one output, a NOR gate 312 with two m inputs and one output, a multiplexer 313 with two inputs which can be selected by means of a control input, an OR gate 314 with m inputs and one output, and an AND gate 315 with two inputs and one output.

The coefficient K₁ is multiplied by the value αⁱ using the multiplier 306. The output of the multiplier 306 is connected to the first input of the adder 308.

The coefficient K₂ is multiplied by the value α²ⁱ using the multiplier 307. The output of the multiplier 307 is connected to the second input of the adder 308.

The multiplications of K₁ with αⁱ and of K₂ with α²ⁱ performed by the multipliers are constant multiplications.

The coefficient K₀ is connected to the third input of the adder 308.

The output of the adder 308 is connected to the input of the NOR gate 311. A correction value

$${cor}_{i}^{2}$$

for the 2-bit error is provided at the output of the NOR gate 311 and fed to the first input (the 1 input) of the multiplexer 313.

In addition, the coefficient K₂ is added to the value αⁱ by means of the adder 309. The output of the adder 309 is connected to the first input of the NOR gate 312.

The value of the syndrome component s₃ is added to the value α³ⁱ by means of the adder 310. The output of the adder 310 is connected to the second input of the NOR gate 312. A correction value

$${cor}_{i}^{1}$$

for the 1-bit error is provided at the output of the NOR gate 312 and fed to the second input (the 0 input) of the multiplexer 313.

The correction signal corᵢ for correcting for the i-th component

$${v}_{i}^{′} in {v}_{i}^{cor} = {v}_{i} + {cor}_{i}$$

of a bit vector

$${v}^{′} = {v}_{1}^{′} , … , {v}_{n}^{′}$$

to be corrected is provided at the output of the multiplexer 313.

Any 1-bit error present is corrected by forming the correction signal

$${cor}_{i}^{1}$$

by feeding

K₂+αⁱ=s₁+αⁱ

and

s₃+α³ⁱ

on m-bit-wide lines in each case to the NOR gate 312, the 1-bit-wide output of which is routed to the 0 input of the multiplexer 313.

The multiplexer 313 is controlled by the control signal d, i.e. the control signal d determines whether the 0 input or the 1 input is connected to the output of the multiplexer 313. The 0 input of multiplexer 313 is connected to the output if the control signal d is equal to 0. Similarly, the 1 input of the multiplexer 313 is connected to the output if the control signal d is equal to 1.

The control signal d is determined as follows: The value of the syndrome component s₁ is present at the OR gate 314. The output of the OR gate 314 is connected to the first input of the AND gate 315. The inverted parity is P present at the second input of the AND gate 315. The output of the AND gate 315 returns the control signal d for the multiplexer 313.

The output of the AND gate 315, i.e. the control signal d, is equal to 1 if s₁≠0 and the parity P is equal to 0, i.e. if a 2-bit error is present. Only then is the 1-input of the multiplexer 313 connected to the output; the error correction of the 2-bit error is performed using the correction signal

$${cor}_{i}^{2} .$$

In this case it is not necessary to additionally determine whether an error has occurred at all. If no error has occurred, then s₁=0 and P=0. The control signal d is equal to 0, the multiplexer 313 connects its 0 input to the output. The correction signal

$${cor}_{i}^{1}$$

for the 1-bit error is 0, so that no false correction is made.
Alternative Embodiment without Multiplexer

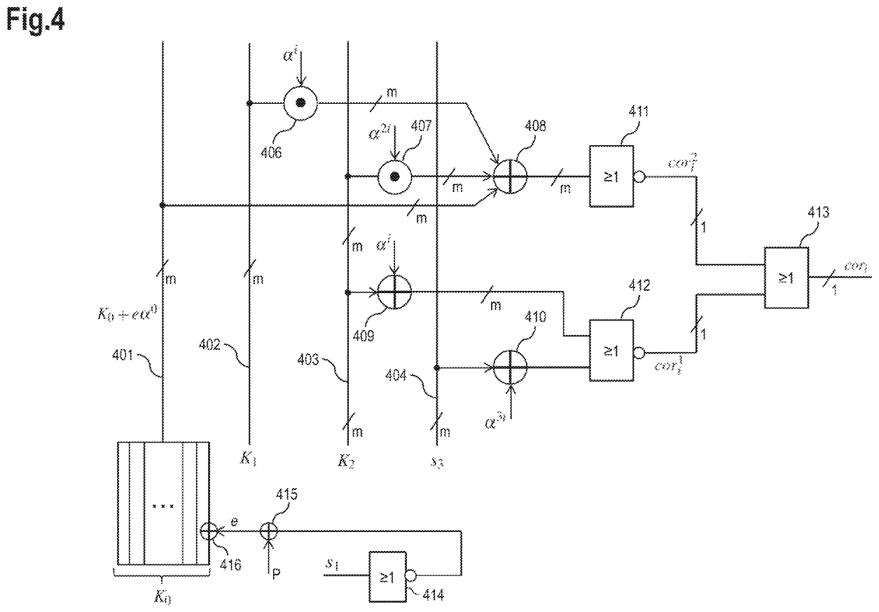

FIG. 4 shows an alternative embodiment of a combination of the fast correction of a 1-bit error with a correction of a 2-bit error.

In contrast to FIG. 3, a modified locator polynomial L₂(x)^{mod} is used instead of the second degree locator polynomial for correcting a 2-bit error, so that it is true in the case of a 2-bit error L₂(x)^{mod}=L₂(x) and in the case of no error or a 1-bit error, L₂(α^{k})^{mod}≠0 applies to all bit positions k to be corrected, as opposed to the locator polynomial L₂(x).

For the coefficients K₀, K₁ and K₂ the following applies as in the example of FIG. 3:

$${K}_{0} = {s}_{1}^{3} + {s}_{3} ,$$

$${K}_{1} = {s}_{1}^{2} ,$$

$${K}_{2} = {s}_{1} .$$

On an m-bit wide line 401 a value K₀+eα⁰ is provided, on an m-bit wide line 402 the coefficient K₁, on an m-bit wide line 403 the coefficient K₂ and on an m-bit wide line 404 the value of the syndrome component s₃ is provided.

Also provided in FIG. 4 are multipliers 406, 407 with m inputs and m outputs each, an adder 408 with three m inputs, adders 409, 410 with two m inputs and m outputs each, a NOR gate 411 with m inputs and one output, a NOR gate 412 with two m inputs and one output, an OR gate 413 with two inputs and one output, a NOR gate 414 with m inputs and one output, an adder 415 with two inputs and one output and an adder 416 with two inputs and one output.

The coefficient K₁ is multiplied by the value αⁱ using the multiplier 406. The output of the multiplier 406 is connected to the first input of the adder 408.

The coefficient K₂ is multiplied by the value α²ⁱ using the multiplier 407. The output of the multiplier 407 is connected to the second input of the adder 408.

The value K₀+eα⁰ is connected to the third input of the adder 408.

The output of the adder 408 is connected to the input of the NOR gate 411. A correction value

$${cor}_{i}^{2}$$

for the 2-bi error is provided at the output of the NOR gate 411 and fed to the first input of the OR gate 413.

In addition, the coefficient K₂ is added to the value αⁱ by means of the adder 409. The output of the adder 409 is connected to the first input of the NOR gate 412.

The value of the syndrome component s₃ is added to the value α³ⁱ by means of the adder 410. The output of the adder 410 is connected to the second input of the NOR gate 412. A correction value

$${cor}_{i}^{1}$$

for the 1-bit error is provided at the output of the NOR gate 412 and fed to the second input of the OR gate 413.

The correction signal corᵢ for correcting for the i-th component

$${v}_{i}^{′} in {v}_{i}^{cor} = {v}_{i} + {cor}_{i}$$

of a bit vector

$${v}^{′} = {v}_{1}^{′} , … , {v}_{n}^{′}$$

to be corrected is provided at the output of the OR gate 413.

Instead of determining the correction signal

$${cor}_{i}^{2}$$

for the 2-bit error and the correction signal

$${cor}_{i}^{1}$$

for the 1-bit error via the multiplexer 313 and the control signal d, in FIG. 4 the correction signals

$${cor}_{i}^{1} and {cor}_{i}^{2}$$

are routed via the OR gate 413 because at most one of the two correction signals

$${cor}_{i}^{1} or {cor}_{i}^{2}$$

can have the value 1.

The locator polynomial L₂(x)^{mod} may be determined according to

$${{L}_{2} ( x )}^{m od} = {s}_{1}^{3} + {s}_{2} + {s}_{1}^{x} x + {s}_{1} {x}^{2} + {α}^{L} \cdot e .$$

with a control signal e defined as follows:

$$e = \{ \begin{matrix}0 & for {s}_{1} \neq 0 and P = 0 \\ 1 & for {s}_{1} \neq 0 and P = 1 \\ 1 & for {s}_{1} = 0 and P = 0\end{matrix} .$$

The control signal e is determined according to equation above in such a way that the 1-bit error and the 2-bit error are corrected in the correct way. Correction of 3-bit errors is not provided in this example.

It is preferable to choose α^{L}=α⁰ in the above equation, since α⁰ has only one binary component unequal to 0. The value

$${K}_{0} = {s}_{1}^{3} + {s}_{3} ,$$

depending on whether the control signal e is equal to 0 or equal to 1, and because

$${α}^{0} = {\underbrace{[ 1 , 0 , … , 0 ]}}_{m}$$

only needs to be inverted in one bit depending on the control signal e.

This is implemented in FIG. 4 as follows: The value of the syndrome component s₁ is applied to the NOR gate 414, the output of the NOR gate 414 assumes the value 1 only if all m bits of the syndrome component s₁ are equal to 0. The output of the NOR gate 414 is connected to the first input of the adder 415, the second input of which is connected to the parity P. The control signal is e provided at the output of the adder 415 and fed to a first input of the adder 416. The second input of the adder 416 is connected to one bit of the coefficient K₀. Thus, a single bit of the coefficient K₀ is inverted depending on the control signal e. This results in the value K₀+eα⁰ that is present on the line 401.

The correction signal

$${cor}_{i}^{2}$$

is equal to 0 if no error or a 1-bit error is present, since in the case of no error or a 1-bit error, L₂(x)^{mod} is always unequal to 0, in contrast to the locator polynomial L₂(x).

The correction signal

$${cor}_{i}^{1}$$

is equal to 0 if there is no error or a 2-bit error present.

Thus, the correction signals

$${cor}_{i}^{2} and {cor}_{i}^{1} ,$$

as shown in FIG. 4, can be combined by means of the OR gate 413. The modified locator polynomial L₂(x)^{mod} is determined from the unmodified locator polynomial L₂(x) by modifying only a single coefficient of L₂(x) in one bit depending on the control signal e.
Fast Correction of the 1-Bit Error Combined with Correction of the 2-Bit Error and the 3-Bit Error

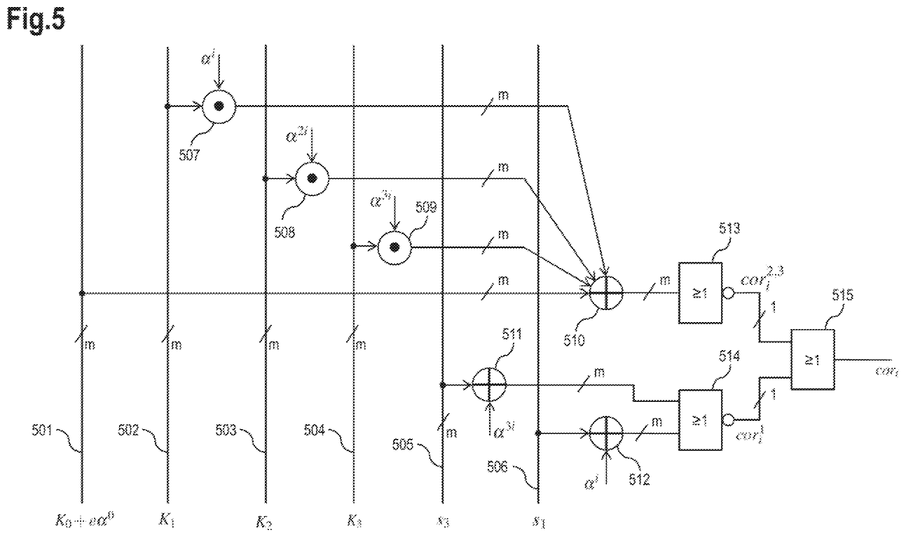

FIG. 5 shows an exemplary embodiment of a combination of the fast correction of a 1-bit error with a correction of a 2-bit error and a correction of a 3-bit error.

For error correction of a 2-bit error or a 3-bit error with a BCH code, the zeros of a third-degree locator polynomial

$$\begin{matrix}{L}_{3} ( x ) = {x}^{3} {K}_{3} + {x}^{2} {K}_{2} + {xK}_{1} + {K}_{0} = \\ = {x}^{3} ( {s}_{1}^{3} + {s}_{3} ) + {x}^{2} ( {s}_{1}^{4} + {s}_{1} {s}_{3} ) ++ \\ x ( {s}_{1}^{2} {s}_{3} + {s}_{5} ) + {s}_{3} ( {s}_{1}^{3} + {s}_{3} ) + {a}_{1}^{6} + {s}_{1} {s}_{5} .\end{matrix}$$

determine the bit positions to be corrected.

In this example, the coefficients are determined as follows:

$${K}_{0} = {s}_{3} ( {s}_{1}^{3} + {s}_{3} ) + {s}_{1}^{6} + {s}_{1} {s}_{5}$$

$${K}_{1} = {s}_{1}^{2} {s}_{3} + {s}_{5} ,$$

$${K}_{2} = {s}_{1}^{4} + {s}_{1} {s}_{3} ,$$

$${K}_{3} = {s}_{1}^{3} + {s}_{3} .$$

The locator polynomial L₃(αⁱ) is equal to 0 if a 1-bit error occurs in any bit position k with

s₁=α^{k},

s₃=α^{3k},

s₅=α^{5k}

or if there is no bit error present, i.e. if

s₁=s₃=s₅=0

is true. In these cases, all coefficients K₀, K₁, K₂ and K₃ of the locator polynomial assume L₃(αⁱ) assume the value 0.

In order to be able to use the third-degree locator polynomial to determine bit positions to be corrected, it must be established whether the bit string is error-free or whether there is a 1-bit error present. Only if the bit string is not error-free and if no 1-bit error is present, can the erroneous bit positions of a 2-bit error and a 3-bit error be identified using the zeros of the third-degree locator polynomial.

In the example described here, instead of the third-degree locator polynomial L₃(x) a modified locator polynomial L₃(x)^{mod} derived from the locator polynomial is used. The modified locator polynomial L₃(x)^{mod} is determined such that
L₃(x)^{mod}=L₃(x) is true if there is a 3-bit error or a 2-bit error and
L₃(α^{k})^{mod}+0 is true if there is no error or a 1-bit error is present for all bit positions k to be corrected.

The modified locator polynomial L₃(x)^{mod} is determined from the locator polynomial L₃(x) by modifying only a single coefficient of L₃(x) in one bit depending on the control signal e.

In this example, the correction signals can be combined via an OR gate, since at most one of the correction signals can be equal to 1.

The modified locator polynomial L₃(x)^{mod} can be determined as follows

L₃(x)^{mod}=x³K₃+x²K₂+xK₁+K₀+eα^{L}

where

$$e = \{ \begin{matrix}1 & for {s}_{1}^{3} + {s}_{3} = 0 \\ 0 & for {s}_{1}^{3} + {s}_{3} \neq 0\end{matrix} ,$$

where, for example, α^{L}=α⁰ can be chosen because α⁰ has only one binary component unequal to 0. The coefficient K₀, because of

$${α}^{0} = {\underbrace{[ 1 , 0 , … , 0 ]}}_{m} ,$$

only has to be inverted in a single bit, depending on whether the control signal e is equal to 0 or 1.

The control signal e can be generated, for example, by transforming the value of the syndrome component s₁ by means of a power value generator into the value

$${s}_{1}^{3} ,$$

which is then added by means of an adder to the value of the syndrome component s₃. The individual bits of the result

$${s}_{1}^{3} + {s}_{3}$$

are submitted to a NOR gate, which outputs the value 1 only if all bits at the input are equal to 0. The value of the control signal e is thus provided at the output of this NOR gate.

On an m-bit wide line 501 a value K₀+eα⁰ is provided, on an m-bit wide line 502 the coefficient K is provided, on an m-bit wide line 503 the coefficient K₂, on an m-bit wide line 504 the coefficient K₃, on an m-bit wide line 505 the value of the syndrome component s₃ is provided, and on an m-bit wide line 506 the value of the syndrome component s₁.

Also provided in FIG. 5 are multipliers 507, 508, 509 with m inputs and m outputs each, an adder 510 with four m inputs and m outputs, adders 511, 512 with two m inputs and m outputs each, a NOR gate 513 with m inputs and one output, a NOR gate 514 with two m inputs and one output, and an OR gate 515 with two inputs and one output.

The coefficient K₁ is multiplied by the value αⁱ using the multiplier 507. The output of the multiplier 507 is connected to the first input of the adder 510.

The coefficient K₂ is multiplied by the value α²ⁱ using the multiplier 508. The output of the multiplier 508 is connected to the second input of the adder 510.

The coefficient K₃ is multiplied by the value α³ⁱ using the multiplier 509. The output of the multiplier 509 is connected to the third input of the adder 510.

The value K₀+eα⁰ is connected to the fourth input of the adder 510.

The output of the adder 510 is connected to the input of the NOR gate 513. A correction value

$${cor}_{i}^{2 , 3}$$

for the 2-bit error or the 3-bit error is provided at the output of the NOR gate 513 and fed to the first input of the OR gate 515.

The value of the syndrome component s₃ is added to the value α³ⁱ by means of the adder 511. The output of the adder 511 is connected to the first input of the NOR gate 514.

The value of the syndrome component s₁ is added to the value αⁱ by means of the adder 512. The output of the adder 512 is connected to the second input of the NOR gate 514. A correction value

$${cor}_{i}^{1}$$

for the 1-bit error is provided at the output of the NOR gate 514 and fed to the second input of the OR gate 515.

The correction signal corᵢ for correcting for the i-th component

$${v}_{i}^{′} in {v}_{i}^{cor} = {v}_{i} + {cor}_{i}$$

of a bit vector

$${v}^{′} = {v}_{1}^{′} , … , {v}_{n}^{′}$$

to be diluted is provided at the output of the OR gate 515.

The 1-bit error in the bit position i is corrected if s₁+αⁱ=0 and s₃+α³ⁱ=0 applies. In this case, as explained, L₃(αⁱ)^{mod}≠0.

If L₃(αⁱ)^{mod}=0, on the other hand, then a correction signal equal to 1 is determined by

$${L}_{3}^{mo d}$$

for the i-th bit position. L₃(αⁱ)^{mod} assumes the value 0 only if a 2-bit error or a 3-bit error is present. If no error or a 1-bit error is present, L₃(αⁱ)^{mod} is determined to be α⁰≠0. The correction signals

$${cor}_{i}^{1} and {cor}_{i}^{2 , 3}$$

for the i-th bit position are combined via the OR gate 515. Only one of the two correction signals

$${cor}_{i}^{1} and {cor}_{i}^{2 , 3}$$

can be unequal to 0.

The modified locator polynomial L₃(x)^{mod} can be determined from the third-degree locator polynomial, for example, by logically XOR-combining the locator polynomial coefficient K₀ component-by-component with a constant value α^{L} if it is indicated that no error or a 1-bit error is present.

It should be noted in this context that in FIGS. 3, 4 and 5 the multipliers 306, 307, 406, 407, 507, 508 and 509 multiply any value of the Galois field by a constant determined by the respective bit position.

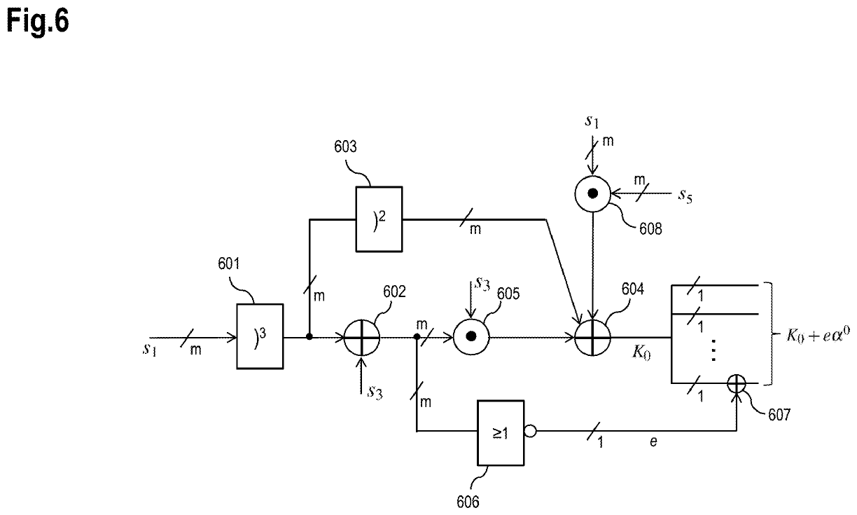

FIG. 6 shows an example implementation of the formation of the value K₀+eα⁰ of the modified locator polynomial L₃(x)^{mod}.

FIG. 6 comprises a third power generator 601 with m inputs and m outputs, an adder 602 with two m inputs and m outputs, an adder 604 with three m inputs and m outputs, a squaring unit 603 with m inputs and m outputs, Galois field multipliers 605, 608 with two m inputs and m outputs each, a NOR gate with m inputs and one output, and an adder 607 with two inputs and one output.

The value of the syndrome component s₁ is modified by means of the third power generator 601 into a value

$${s}_{1}^{3}$$

which is supplied to the squaring unit 603 and the first input of the adder 602. At the output of the squaring unit 603 the value

$${s}_{1}^{6}$$

is present, which is supplied to the first input of the adder 604. The second input of the adder 602 receives the value of the syndrome component s₃, and the output of the adder 602 is connected to the first input of the Galois field multiplier 605, at the second input of which the value of the syndrome component s₃ is supplied. The value

$$( {s}_{1}^{3} + {s}_{3} ) {s}_{3}$$

is provided at the output of the Galois field multiplier 605. The output of the Galois field multiplier 605 is connected to the second input of the adder 604.

By means of the Galois field multiplier 608, the values of the syndrome components s₁ and s₅ are multiplied. The output of the Galois field multiplier 608 is connected to the third input of the adder 604. At the output of the adder 604 therefore, the value

$${K}_{0} = ( {s}_{1}^{3} + {s}_{3} ) {s}_{3} + {s}_{1}^{6} + {s}_{1} {s}_{5}$$

is provided.

Furthermore, the output of the adder 602, which provides the value

$${s}_{1}^{3} + {s}_{3} ,$$

is connected to the input of the NOR gate 606. The control signal e is provided at the output of the NOR gate 606. The control signal e only returns the value 1 if all bits of the signal

$${s}_{1}^{3} + {s}_{3}$$

are equal to 0.

The control signal e is fed to the first input of the adder 607. The second input of the adder 607 is connected to one bit of the signal provided at the output of adder 604. The adder 607 inverts this bit depending on the value of the control signal e: if the control signal e is equal to 1, the bit on the line that contains the adder 607 is inverted.

From the value K₀ provided at the output of adder 604, the value K₀+e·α⁰ is obtained after the adder 607.

The coefficients K₁, K₂ and K₃ can be determined in the same way by means of power generators, multipliers and adders.

As explained, the coefficients K₀, K₁, K₂ and K₃ assume the value 0 in the error-free case or in the case of a 1-bit error with

$${s}_{1}^{3} = {s}_{3} .$$

However, since for

$${s}_{1}^{3} + {s}_{3} = 0$$

one bit of K₀ is inverted, which corresponds to an addition of α⁰≠0 to K₀, for a 1-bit error or a 0-bit error L₃(αⁱ)^{mod}=α⁰+0 is true.

What is claimed is:

1. A method, comprising
determining, based on a BCH code, an error syndrome for a vector, the error syndrome comprising a first syndrome component s₁ and a second syndrome component s₃; and
correcting an i-th bit of the vector based on a combination of s₁ and a first element of a Galois field and a combination of s₃ and a second element of the Galois field;
wherein the second element of the Galois field is determined based on the first element of the Galois field.

2. The method of claim 1, comprising correcting the i-th bit in response to the first element of the Galois field being equal to the element of the Galois field assigned to the i-th bit position.

3. The method of claim 1, comprising correcting the i-th bit in response to
s₁ combined with first element of the Galois field ∝ⁱ being equal to 0, and
s₃ combined with the second element of the Galois field ∝³ⁱ being equal to 0,
wherein the second element of the Galois field is determined as the third power of the first element of the Galois field,
wherein the Galois field is determined to GF(2^{m}).

4. The method of claim 3, wherein the elements of the Galois field in their vector representation are m-component vectors and
(s₁+αⁱ,s₃+α³ⁱ)
is a 2m-component binary vector.

5. The method of claim 1, wherein the BCH code is a shortened BCH code.

6. The method of claim 1, wherein the BCH code is a BCH code with parity.

7. The method of claim 6, comprising determining a correction signal that triggers correction of a bit in the vector based on whether the first syndrome component or the second syndrome component is unequal to 0 and a determined parity comprises a value that does not correspond to a one-bit error.

8. The method of claim 1, comprising determining a correction signal for one bit of a multi-bit error in response to determining that an error has occurred that is not a 1-bit error.

9. The method of claim 1, comprising
determining a modified locator polynomial by adding a constant to a coefficient of a locator polynomial in response to either 0 or 1 errors being determined; and
correcting the i-th bit using the modified locator polynomial.

10. The method of claim 1, comprising generating a correction signal for a bit position based on a logical OR combination of a first correction signal determined for the bit position for correcting a 1-bit error and a second correction signal determined for the bit position for correcting a multi-bit error.

11. A device, comprising
a first partial circuit configured to determine a first correction signal based on whether 0 or 1 errors are determined in a vector,
a second partial circuit configured to determine a second correction signal based on whether least one multi-bit error is determined in the vector,
wherein the first partial circuit and the second partial circuit are configured in such a way that either the first correction signal or the second correction signal, but not both correction signals, is active.

12. The device of claim 11, wherein the first correction signal is sufficient to indicate that no correction is necessary.

13. The device of claim 11, wherein in response to an error, an at least one multi-bit error is corrected using the second correction signal when the first correction signal does not trigger an error correction.

14. The device of claim 11, wherein the first partial circuit comprises a gate logic, that generates the first correction signal for an i-th bit, by combining a first syndrome component of an error syndrome with a first element of a Galois field and combining a second component of the error syndrome with a second element of the Galois field, wherein the second element of the Galois field is determined by the first element of the Galois field.

15. The device of claim 14, wherein the error syndrome has a first syndrome component s₁ and a second syndrome component s₃, further wherein the correction signal triggers a correction of the i-th bit in response to
s₁ combined with the first element of the Galois field ∝ⁱ being equal to 0, and
s₃ combined with the second element of the Galois field ∝³ⁱ being equal to 0,
wherein the second element of the Galois field is determined as the third power of the first element of the Galois field, and
wherein Galois field is determined to GF(2^{m}).

16. The device of claim 14, wherein the second partial circuit is configured to generate a control signal based on the first syndrome component s₁, such that when the first partial circuit indicates that there is no error or a 1-bit error present, the second partial circuit indicates that no multi-bit error is present.

17. The device of claim 11, wherein the second partial circuit comprises circuitry configured to perform logical combinations of multiple syndrome components of an error signal with multiple elements of the Galois field.

18. A device, comprising circuitry configured to
receive an error syndrome for a vector, the error syndrome comprising a first syndrome component s₁ and a second syndrome component s₃; and
correct an i-th bit of the vector based on a combination of s₁ and a first element of a Galois field and a combination of s₃ and a second element of the Galois field;
wherein the second element of the Galois field is determined based on the first element of the Galois field.

19. The device of claim 18, comprising
first combination circuitry configured to combine s₁ with first element of the Galois field ∝¹,
circuitry configured to raise the first element of the Galois field to the third power to determine the second element of the Galois field, and
second combination circuitry configured to combine s₃ combined with the second element of the Galois field ∂³ⁱ, and
first correction signal circuitry configured to generate a correction signal that triggers correction of the i-th bit when the output of the first combination circuitry and the second combination circuitry is 0,
wherein the Galois field is determined to GF(2^{m}).

20. The device of claim 18, comprising further circuitry configured to determine a second correction signal for one bit of a multi-bit error in response to determining that an error has occurred that is not a 1-bit error.
